(19) United States
(12) Patent Application Publication
(10) Pub. No.: US 2007/0232084 A1
(43) Pub. Date: Oct. 4, 2007

(54) Manufacturing method for semiconductor device

(76) Inventor: Masahiro Murayama, Kyoto-shi (JP)

Correspondence Address: MCDERMOTT WILL & EMERY LLP, 600 13TH STREET, N.W., WASHINGTON, DC, 20005-3096, US

(21) Appl. No.: 11/723,959

(22) Filed: Mar. 22, 2007

(30) Foreign Application Priority Data
Mar. 22, 2006 (JP) P2006-079521

(51) Int. Cl. H01L 21/00

(52) U.S. Cl. 438/796

(57) ABSTRACT

A manufacturing method for a semiconductor device according to the present invention includes the steps of: growing a p-type contact layer formed of a p-type GaN layer; forming an insulating film on a surface of the p-type contact layer, on which a p-side electrode is to be formed, by coating an insulating film material on the surface and thereafter baking the insulating film material; and annealing the p-type semiconductor layer in a state where the insulating film is formed on the p-type contact layer.

### CROSS REFERENCE TO RELATED APPLICATIONS AND INCORPORATION BY REFERENCE

This application is based upon and claims the benefit of prior Japanese Patent Application P2006-79521 filed on Mar. 22, 2006; the entire contents of which are incorporated by reference herein.

### BACKGROUND OF THE INVENTION

1. Field of the Invention

The present invention relates to a manufacturing method for a semiconductor device including a p-type contact layer formed of a p-type GaN system semiconductor layer.

2. Description of the Related Art

Heretofore, a manufacturing method for a semiconductor device including a p-type contact layer formed of a p-type GaN system semiconductor layer has been known. In the manufacturing method for the semiconductor device including the p-type contact layer, the p-type contact layer is grown by using hydrogen gas as carrier gas. Thereafter, in order to release hydrogen captured into the p-type contact layer, the p-type semiconductor layer is annealed. In such a way, bonding between an acceptor and the hydrogen in the p-type semiconductor layer can be cut, and accordingly, the acceptor can be activated, and the p-type semiconductor layer can be turned into the p type.

However, when the p-type contact layer formed of the p-type GaN system semiconductor layer is annealed at high temperatures (800° C. or higher), there has been a problem that the p-type GaN system semiconductor layer in the p-type contact layer is thermally decomposed, resulting in release of nitrogen to the outside. Meanwhile, when the p-type contact layer is annealed at low temperatures in order to prevent the release of the nitrogen, there has been a problem that the above-described activation of the acceptor cannot be sufficiently made. In this connection, there has been known a technology for preventing the nitrogen from being released to the outside when the p-type contact layer is annealed at the high temperatures.

In Patent Document 1 (Japanese Patent No. 2540791), there is disclosed a manufacturing method for a semiconductor device, in which a cap layer made of SiO₂, which is formed by a plasma CVD method, is formed on a surface of a p-type contact layer, followed by annealing. As described above, the cap layer is formed on the surface of the p-type contact layer, thus making it possible to suppress the release of the nitrogen to the outside from the surface of the p-type contact layer.

However, as a result of an assiduous study, the inventor of this application has found out that, when the cap layer made of SiO₂ is formed by the plasma CVD method as in the manufacturing method for a semiconductor device in Patent Document 1, there is such a problem that the surface of the p-type contact layer is roughened, a resistance value between the p-type contact layer and a p-side electrode becomes extremely large, and a current hardly flows therebetween.

### SUMMARY OF THE INVENTION

The present invention has been created in order to solve the above-described problem. It is an object of the present invention to provide a manufacturing method for a semiconductor device, which is capable of reducing the resistance value between the p-type contact layer and the electrode while suppressing the nitrogen in the p-type contact layer from being released by the annealing.

A first aspect of the present invention provides a manufacturing method for a semiconductor device, comprising the steps of forming a p-type semiconductor layer comprising a p-type contact layer for an electrode to be formed, the p-type contact layer being formed of a p-type GaN system semiconductor layer; forming an insulating film on a surface of the p-type contact layer for the electrode to be formed, including coating an insulating film material on the surface; and annealing the p-type semiconductor layer.

A second aspect of the present invention is a variation on the first aspect, the annealing comprises annealing the p-type semiconductor layer at temperatures of 900° C. or higher.

A third aspect of the present invention is a variation on the first aspect, the annealing comprises annealing the p-type semiconductor layer in atmospheric-pressure atmospheres containing nitrogen gas.

In the manufacturing method for a semiconductor device according to the present invention, the p-type semiconductor layer is annealed in a state where the insulating film is formed on the p-type contact layer, whereby an acceptor of the p-type semiconductor layer is activated. Accordingly, the nitrogen can be suppressed from being released from the p-type contact layer. Therefore, the p-type semiconductor layer can be annealed at higher temperatures as compared with the case where the insulating film is not formed. In such a way, the activation of the p-type impurities such as Mg in the p-type semiconductor layer can be enhanced. Accordingly, the resistance value of the p-type semiconductor layer can be reduced. Moreover, the nitrogen can be suppressed from coming out of the p-type contact layer by the insulating film in the case of the annealing. Accordingly, it is not necessary to perform the annealing in the pressurized atmosphere containing the nitrogen. In such a way, a manufacturing process of the semiconductor device can be simplified.

Moreover, the insulating film is formed on the p-type contact layer by coating the insulating film material thereon, thus making it possible to prevent damage on the p-type contact layer, which is given thereto in the case of forming the insulating film on the p-type contact layer by the plasma CVD method. In such a way, an increase of the resistance value between the p-type contact layer and the electrode, which is caused by the damage on the p-type contact layer, can be prevented. Accordingly, the resistance value between the p-type contact layer and the electrode is reduced, thus making it possible to form good ohmic contacts therebetween.

### BRIEF DESCRIPTION OF DRAWINGS

FIG. 1 shows a cross-sectional structure of a gallium nitride system semiconductor light-emitting device manufactured by a manufacturing method of the present invention.

FIG. 2 is a view showing a cross-sectional structure in the respective manufacturing steps of the gallium nitride system semiconductor light-emitting device according to an embodiment.

FIG. 3 is a view showing a cross-sectional structure in the respective manufacturing steps of the gallium nitride system semiconductor light-emitting device according to the embodiment.

FIG. 4 is a view showing a cross-sectional structure in the respective manufacturing steps of the gallium nitride system semiconductor light-emitting device according to the embodiment.

FIG. 5 is a view showing a cross-sectional structure in the respective manufacturing steps of the gallium nitride system semiconductor light-emitting device according to the embodiment.

FIG. 6 is a view showing a cross-sectional structure of a sample fabricated for an experiment.

FIG. 7 is a graph showing a relationship between a current flown through the sample and a voltage.

### DETAILED DESCRIPTION OF THE INVENTION

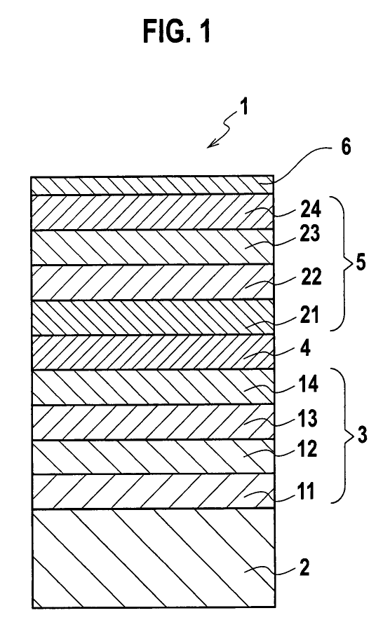

A description will be made below of a first embodiment of the present invention. FIG. 1 shows a cross-sectional structure of a gallium nitride system semiconductor light-emitting device manufactured by a manufacturing method for a semiconductor device according to the present invention.

As shown in FIG. 1, a gallium nitride system semiconductor light-emitting device 1 is formed by sequentially stacking an n-type semiconductor layer 3, an active layer 4, and a p-type semiconductor layer 5 on an n-type GaN substrate 2. Moreover, a metal-made p-side electrode 6 is formed on an upper surface of the p-type semiconductor layer 5, and in the n-type semiconductor layer 3, an n-side electrode (not shown) is formed on an n-type contact layer 11 to be described later.

In the n-type semiconductor layer 3, in order from the GaN substrate 2 side, there are sequentially stacked the n-type contact layer 11 formed of an n-type GaN layer, an n-type superlattice clad layer 12 with a thickness of approximately 13000 Å, in which 260 layers of n-type Al_{0.16}Ga_{0.84}N layers with a thickness of approximately 25 Å and 260 layers of n-type GaN layers with a thickness of approximately 25 Å are stacked on each other, an n-type guide layer 13 formed of an n-type GaN layer with a thickness of approximately 700 Å, and an n-type superlattice layer 14 in which a plurality of n-type InGaN layers and a plurality of n-type GaN layers are alternately stacked.

In the active layer 4, a plurality of barrier layers and a plurality of well layers, which are formed of InGaN layers different from each other in composition ratio of In, are alternately stacked.

In the p-type semiconductor layer 5, in order from the active layer 4 side, there are sequentially stacked a p-type electron barrier layer 21 formed of an Al_{0.2}Ga_{0.8}N layer with a thickness of approximately 200 Å, a p-type guide layer 22 with a thickness of approximately 1000 Å, a p-type superlattice clad layer 23 with a thickness of approximately 4000 Å, in which 80 layers of p-type Al_{0.16}Ga_{0.84}N layers with a thickness of approximately 25 Å and 80 layers of p-type GaN layers with a thickness of approximately 25 Å are stacked on each other, and a p-type contact layer 24 formed of a p-type GaN layer with a thickness of approximately 500 Å.

In the gallium nitride system semiconductor light-emitting device 1, when carriers are supplied from the n-side electrode and the p-side electrode 6, the carriers are injected into the active layer 4 through the n-type semiconductor layer 3 and the p-type semiconductor layer 5. Then, the carriers injected into the active layer 4 are bonded to each other, thereby emitting light.

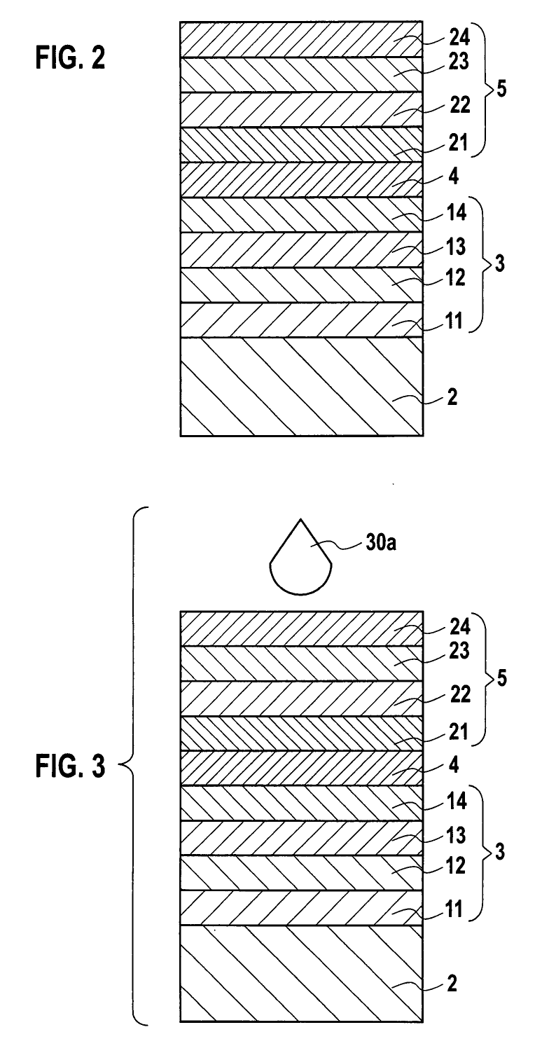

Next, a description will be made of a manufacturing method for the above-described gallium nitride system semiconductor light-emitting device with reference to FIG. 2 to FIG. 5. FIG. 2 to FIG. 5 are views showing cross-sectional structures of the respective manufacturing steps of the gallium nitride system semiconductor light-emitting device according to the embodiment.

First, as shown in FIG. 2, by an already known method such as an MOCVD method, the n-type contact layer 11, the n-type superlattice clad layer 12, and the n-type guide layer 13 are sequentially grown on the n-type GaN substrate 2 in a state where the GaN substrate 2 is held at growth temperatures of approximately 1050° C. Next, the temperatures of the GaN substrate 2 is dropped down to growth temperatures of approximately 780° C., and the n-type superlattice layer 14 and the active layer 4 are sequentially grown thereon. Thereafter, the temperatures of the GaN substrate 2 is raised up to growth temperatures of approximately 1070° C., and the p-type electron barrier layer 21 is grown thereon. Next, the temperatures of the GaN substrate 2 is dropped down to growth temperatures of approximately 1000° C., and the p-type guide layer 22 is grown thereon. Thereafter, the temperatures of the GaN substrate 2 is raised up to growth temperatures of approximately 1050° C., and the p-type superlattice clad layer 23 is grown thereon. Next, in a state where the temperatures of the GaN substrate 2 is dropped down to the temperatures of approximately 1000° C., the p-type contact layer 24 formed of the p-type GaN layer with the thickness of approximately 500 Å is grown thereon.

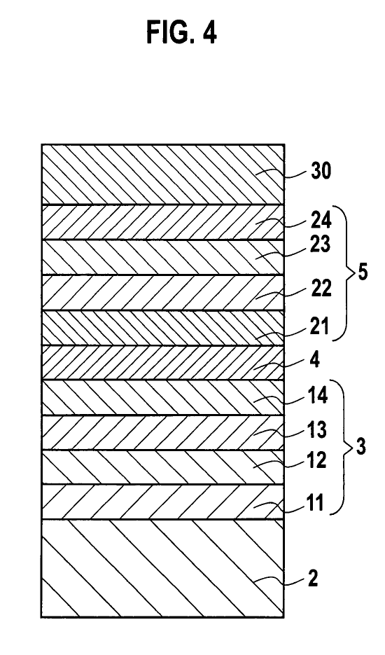

Next, an insulating film 30 with a thickness of approximately 1000 Å, which is made of SiO₂, is formed on the p-type contact layer 24 by coating and baking. Specifically, as shown in FIG. 3, an insulating film material 30a in which polysilazane is dissolved in a dibutyl ether solution is dropped on the p-type contact layer 24. Next, as shown in FIG. 4, the one in which the insulating film material 30a is spread and coated over an upper surface of the p-type contact layer 24 by a spin coat method is subjected to hydrolysis or polycondensation reaction, and thereafter, is subjected to multi-stage baking, whereby the insulating film 30 made of SiO₂ is formed. Although conditions for the multi-stage baking vary depending on the insulating film 30 to be formed, for example, it is possible to apply multi-stage baking performed in such stages where the baking is performed at approximately 220° C. for two minutes, then at approximately 350° C. for two minutes, and finally at approximately 400° C. for 30 minutes. Note that, though the above-described forming step of the insulating film 30 may be performed plural times in the case where the thickness of the insulating film 30 is set to be more than 1000 Å, it is desirable that the thickness of the insulating film 30 be set to be 10000 Å or less for the purpose of preventing a crack of the semiconductor layer. The thickness of the insulating film 30 is set to be 10000 Å or less as described above, thus making it possible to prevent a breakage such as the crack of the p-type contact layer 24, which is caused by a difference in thermal expansion coefficient between the p-type contact layer 24 and the insulating film 30.

Next, the p-type semiconductor layer 5 including the p-type contact layer 24 is annealed in an atmospheric-pressure atmospheres containing nitrogen gas of temperatures of approximately 900° C. or higher or containing nitrogen gas and oxygen of those temperatures. In such a way, an acceptor (Mg) in the p-type semiconductor layer 5 including the p-type contact layer 24 is activated, and the p-type semiconductor layer 5 is turned into the p type.

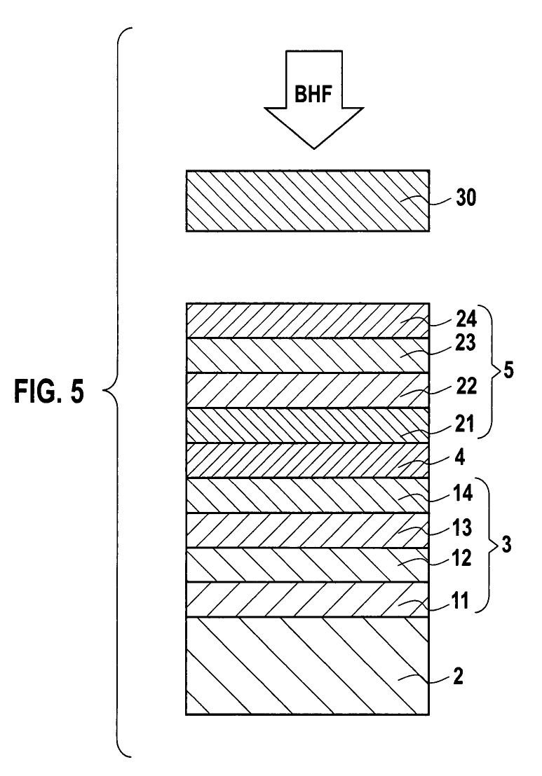

Next, as shown in FIG. 5, the insulating film 30 is wet-etched by a BHF (ammonium hydrogen difluoride) solution of temperatures of approximately 25° C. with a concentration of approximately 14.9%, whereby the insulating film 30 is removed from the upper surface of the p-type contact layer 24. The insulating film 30 is formed and then removed by the wet etching as described above, thus making it possible to remove, together with the insulating film 30, many natural oxide films and contaminants on the surface of the p-type contact layer 24, on which the p-side electrode 6 is to be formed.

Next, after the p-side electrode 6 is formed by the already known method, ohmic contacts are formed by electron beam irradiation or annealing. Finally, an n-side electrode is formed, and the gallium nitride system semiconductor light-emitting device 1 is completed.

As described above, in the manufacturing method for a gallium nitride system semiconductor light-emitting device according to the present invention, the acceptor of the p-type semiconductor layers 21 to 24 is activated in a state where the insulating film 30 is formed on the p-type contact layer 24. Accordingly, even if the annealing is performed at the temperatures of approximately 900° C. or higher, the nitrogen can be suppressed from being released from the p-type contact layer 24. In such a way, the activation of Mg of the p-type contact layer 24 is enhanced, thus making it possible to reduce a resistance value between the p-type contact layer 24 and the p-side electrode 6.

Moreover, the insulating film material 30a is coated on the p-type contact layer 24 as described, whereby the insulating film 30 is formed thereon. In such a way, damage on the p-type contact layer, which is given thereto in the case of forming the insulating film on the p-type contact layer by the plasma CVD method, can be prevented. In such a way, an increase of the resistance value between the p-type contact layer 24 and the p-side electrode 6, which is caused by the damage on the p-type contact layer 24, can be prevented. Accordingly, good ohmic contacts can be formed between the p-type contact layer 24 and the p-side electrode 6.

Furthermore, the insulating film 30 is formed on the p-type contact layer 24, whereby the nitrogen can be suppressed from being released from the p-type contact layer 24. Accordingly, the p-type contact layer 24 can be annealed in the atmospheric-pressure atmospheres containing the nitrogen gas. As a result, an annealing step can be simplified.

Next, with reference to the drawings, a description will be made of an experiment performed for the purpose of proving such an effect that the resistance value between the p-type contact layer and the p-side electrode is reduced by annealing the p-type contact layer after the insulating film is formed on the p-type contact layer.

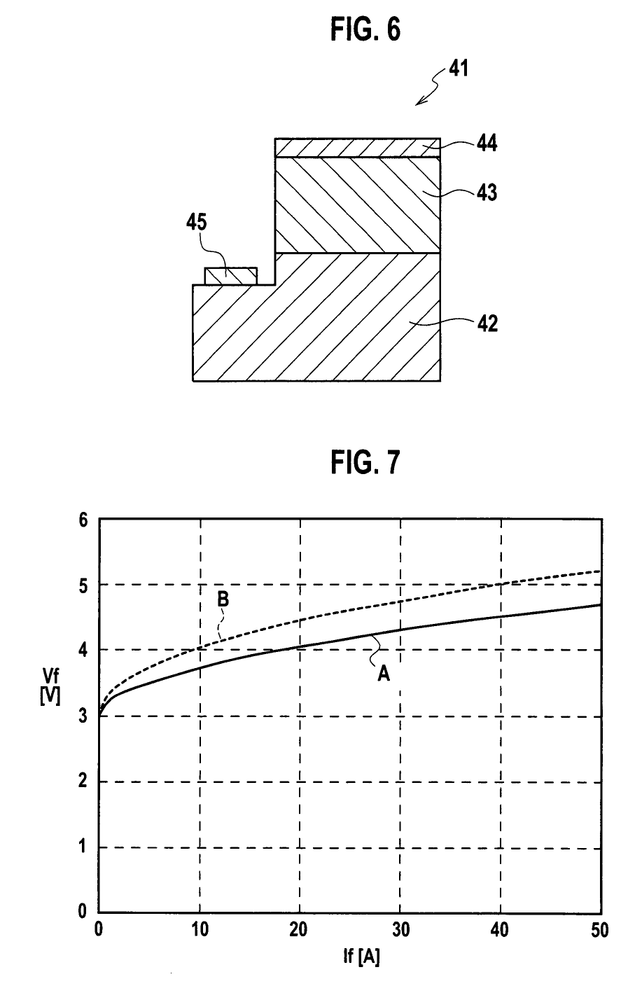

First, a description will be made of samples according to the present invention and a comparative example, which have been fabricated in order to perform the above-described experiment. FIG. 6 is a view showing a cross-sectional structure of each sample fabricated for the experiment.

As shown in FIG. 6, the sample 41 includes an n-type GaN layer 42, and a p-type GaN layer 43 formed on the n-type GaN layer 42. A p-side electrode 44 made of Pd and Au is formed on the p-type GaN layer 43, and an n-side electrode 45 made of Ti and Al is formed on the n-type GaN layer 42.

The sample 41 was fabricated in such a manner that the p-type GaN layer 43 and the p-side electrode 44 made of Pd/Au were sequentially stacked on the n-type GaN layer 42, then the p-side electrode 44, the p-type GaN layer 43, and a part of the n-type GaN layer 42 were mesa-etched, and the n-side electrode 45 made of Ti/Al was formed on a part of the exposed n-type GaN layer 42.

Here, in the sample 41 according to the present invention, after the p-type GaN layer 43 was formed, the insulating film with the thickness of approximately 1000 Å was formed based on the manufacturing method described in the foregoing embodiment before the p-side electrode 44 was formed. Thereafter, the sample 41 was annealed in the atmospheric-pressure atmospheres of the nitrogen gas at approximately 910° C. for approximately 10 minutes, and the insulating film was then removed by the BHF solution. Meanwhile, the sample 41 for comparison was annealed in the atmospheric-pressure atmospheres of the nitrogen gas at approximately 800° C. for approximately 10 minutes without forming the insulating film after the p-type GaN layer 43 was formed.

First, a description will be made of an experimental result of investigating current-voltage characteristics with reference to FIG. 7. Note that an axis of abscissas represents a current that was flown between the p-side electrode 44 and the n-side electrode 45, and that an axis of ordinates represents a voltage in that case. In this experiment, the current thus flown was gradually increased, and voltage values at the respective current values were measured.

As shown in FIG. 7, it is understood that the resistance value in the experimental result (refer to a curve A) of the sample 41 according to the present invention, which was annealed in the state where the insulating film was formed on the p-type GaN layer 43, is lower than the resistance value in the experimental result (refer to a curve B) of the sample 41 according to the comparative example, which was annealed without forming the insulating film on the p-type GaN layer 43. It is considered that this was caused by the following. Specifically, the sample 41 according to the present invention was annealed in the state where the insulating film was formed on the p-type GaN layer 43, thus making it possible to suppress the nitrogen from coming out of the p-type GaN layer 43 as compared with the sample 41 according to the comparative example.

Next, a description will be made of an experiment performed for the purpose of proving enhancements of resistivity and hole concentration of the p-type contact layer. The resistivity and the hole concentration were measured by the van der Pauw method in such a manner that the rectangular p-type GaN layer was formed and electrodes were provided on four corners of the p-type GaN layer.

First, a description will be made of an experimental result of measuring the resistivity. As a sample according to the present invention, a p-type GaN layer annealed at approximately 910° C. for approximately 10 minutes in a state where the insulating film was formed thereon by the above-described manufacturing method was fabricated. Meanwhile, as a sample for comparison, a p-type GaN layer annealed at approximately 800° C. for approximately ten minutes without forming the insulating film thereon was fabricated. While the resistivity of the p-type GaN layer as the above-described sample according to the present invention became approximately 1.74 Ω·cm, the resistivity of the p-type GaN layer as the sample according to the comparative example became approximately 2.31 Ω·cm that was equivalent to approximately 1.3 times that of the sample according to the present invention. Also from this fact, it is understood that the resistance value of the p-type GaN layer according to the present invention is reduced.

Next, a description will be made of an experimental result of measuring the hole concentration. As samples according to the present invention, there were fabricated a p-type GaN layer annealed at approximately 900° C. for approximately 10 minutes in the state where the insulating film was formed thereon by the above-described manufacturing method, and a p-type GaN layer annealed at approximately 925° C. for ten minutes in the above-described state. Meanwhile, as a sample for comparison, a p-type GaN layer annealed at approximately 800° C. for approximately ten minutes without forming the insulating film thereon was fabricated. With regard to the hole concentrations of the p-type GaN layers according to the present invention, the hole concentration of the sample annealed at approximately 900° C. became approximately 8.27×10¹⁷ cm⁻³, and the hole concentration of the sample annealed at approximately 925° C. became approximately 8.91×10¹⁷ cm⁻³. Meanwhile, the hole concentration of the p-type GaN layer for comparison, which was annealed at approximately 800° C., became approximately 7.41×10¹⁷ cm⁻³. Hence, it is understood that the hole concentration of the p-type GaN layer fabricated by the manufacturing method according to the present invention is enhanced more than that of the p-type GaN layer for comparison. Also from this fact, it is understood that the manufacturing method according to the present invention can reduce the resistance value of the p-type GaN layer.

The description has been made above in detail of the present invention by using the foregoing embodiment; however, it is obvious that the present invention is not limited to the embodiment described in this specification. The present invention can be modified and carried out within the gist and scope of the present invention defined by the description of the scope of claims. Specifically, the description of this specification is a mere example of the present invention, and does not allow the present invention to be interpreted in any restrictive meaning at all. A description will be made below of a modified embodiment in which the above-described embodiment is partially modified.

For example, though the insulating film 30 made of SiO₂ has been used in the above-described embodiment, an insulating film made of another oxide or nitride such as SiN may be used.

Moreover, though the BHF solution has been used as acid that removes the insulating film 30 in the above-described embodiment, another acidic solution such as a hydrofluoric acid solution can also be used in place of the BHF solution.

Furthermore, though the insulating film material 30a has been dropped down and then coated in the above-described embodiment, the insulating film material 30a may be coated on the p-type contact layer 24 by a spray and the like. Moreover, after the insulating film material is coated, the insulating film may be formed not by the baking but by irradiating an electron beam or an ultraviolet beam thereonto.

Furthermore, though the p-type contact layer 24 has been composed of the p-type GaN layer in the above-described embodiment, the p-type contact layer 24 may be composed of another p-type GaN system semiconductor layer such as a p-type InGaN layer.

As described above, it is a matter of course that the present invention incorporates various embodiments and the like, which are not described herein. Hence, the technical scope of the present invention is defined only by the following claims reasonable from the foregoing description.

What is claimed is:

1. A manufacturing method for semiconductor devices, comprising the steps of:
forming a p-type semiconductor layer comprising a p-type contact layer for an electrode to be formed, the p-type contact layer being formed of a p-type GaN system semiconductor layer;
forming an insulating film on a surface of the p-type contact layer for the electrode to be formed, including coating an insulating film material on the surface; and
annealing the p-type semiconductor layer.

2. The manufacturing method as claimed in claim 1, wherein:
the annealing comprises annealing the p-type semiconductor layer at temperatures of 900° C. or higher.

3. The manufacturing method as claimed in claim 1, wherein:
the annealing comprises annealing the p-type semiconductor layer in atmospheric-pressure atmospheres containing nitrogen gas.
